(19) United States
(12) Patent Application Publication
(10) Pub. No.: US 2026/0002542 A1
(43) Pub. Date: Jan. 1, 2026

(54) AIR MOVING DEVICE

(71) Applicant: xMEMS Labs, Inc., Santa Clara, CA (US)

(72) Inventors: Martin George Lim, Hillsborough, CA (US); Chiung C. Lo, San Jose, CA (US); Wen-Chien Chen, New Taipei City (TW); Jye Ren, Taipei City (TW); JengYaw Jiang, Saratoga, CA (US)

(73) Assignee: xMEMS Labs, Inc., Santa Clara, CA (US)

(21) Appl. No.: 19/315,870

(22) Filed: Sep. 2, 2025

Related U.S. Application Data
(63) Continuation-in-part of application No. 19/007,580, filed on Jan. 2, 2025.
(60) Provisional application No. 63/618,391, filed on Jan. 8, 2024.
(60) Provisional application No. 63/664,713, filed on Jun. 26, 2024.
(60) Provisional application No. 63/680,620, filed on Aug. 8, 2024.
(60) Provisional application No. 63/689,875, filed on Sep. 3, 2024.
(60) Provisional application No. 63/689,875, filed on Sep. 3, 2024.
(60) Provisional application No. 63/693,176, filed on Sep. 10, 2024.

(51) Int. Cl. F04D 23/00; H05K 7/20

(52) U.S. Cl. CPC F04D 23/00; H05K 7/20136

(57) ABSTRACT

An air moving device includes a film structure, a first actuator and a second actuator. The film structure includes a flap pair, wherein the flap pair includes a first flap and a second flap opposite to each other. The first actuator is disposed on the first flap, and the second actuator is disposed on the second flap. The first actuator includes a first electrode and a second electrode, and the second actuator includes a third electrode and a fourth electrode. The first electrode receives a first demodulation signal and the third electrode receives a second demodulation signal, such that the flap pair performs a differential-mode movement. The second electrode and the fourth electrode receive a modulation signal, such that the flap pair performs a common-mode movement.

### CROSS REFERENCE TO RELATED APPLICATIONS

This application is a continuation-in-part of U.S. application Ser. No. 19/007,580, filed on Jan. 2, 2025, which claims the benefit of U.S. Provisional Application No. 63/618,391, filed on Jan. 8, 2024, and claims the benefit of U.S. Provisional Application No. 63/664,713, filed on Jun. 26, 2024, and claims the benefit of U.S. Provisional Application No. 63/680,620, filed on Aug. 8, 2024, and claims the benefit of U.S. Provisional Application No. 63/689,875, filed on Sep. 3, 2024, and claims the benefit of U.S. Provisional Application No. 63/693,176, filed on Sep. 10, 2024. Further, this application claims the benefit of U.S. Provisional Application No. 63/689,875, filed on Sep. 3, 2024. The contents of these applications are incorporated herein by reference.

### BACKGROUND OF THE INVENTION

### 1. Field of the Invention

The present invention relates to an air moving device, and more particularly, to air moving device capable of producing an airflow with suitable direction for suitable use.

### 2. Description of the Prior Art

Unless otherwise indicated herein, the approaches described in this section are not prior art to the claims in this application and are not admitted as prior art by inclusion in this section.

In modern electronics, the ongoing trend towards device miniaturization and increased component density has made thermal management a critical challenge. On compact circuit boards, the close proximity of electronic components and the presence of multiple heat sources can severely compromise airflow and heat dissipation efficiency. Furthermore, the limited space on the front side of these boards makes it increasingly difficult to mount traditional cooling solutions.

Conventional thermal solutions, which often include discrete fans, heat sinks, or other bulky mechanical devices, are difficult to integrate into today's highly compact systems, particularly in mobile devices like smartphones and tablets. This has created a significant need for a more compact, highly efficient, and seamlessly integrated cooling solution to meet the demands of modern electronic products.

Therefore, it is necessary to improve the prior art.

### SUMMARY OF THE INVENTION

It is therefore a primary objective of the present invention to provide an air moving device, to improve over disadvantages of the prior art.

An embodiment of the present invention provides an air moving device including a film structure, a first actuator and a second actuator. The film structure includes a flap pair, wherein the flap pair includes a first flap and a second flap opposite to each other. The first actuator is disposed on the first flap, and the second actuator is disposed on the second flap. The first actuator includes a first electrode and a second electrode, and the second actuator includes a third electrode and a fourth electrode. The first electrode receives a first demodulation signal and the third electrode receives a second demodulation signal, such that the flap pair performs a differential-mode movement. The second electrode and the fourth electrode receive a modulation signal, such that the flap pair performs a common-mode movement.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of an air moving device according to an embodiment of the present invention.

FIG. 2 is a schematic diagram of air moving devices according to embodiments of the present invention.

FIG. 3 is a schematic diagram of an air moving device according to an embodiment of the present invention.

FIG. 4 is a schematic diagram of an air moving device according to an embodiment of the present invention.

FIG. 5 is a schematic diagram of an air moving device according to an embodiment of the present invention.

FIG. 6 is a schematic diagram of an air moving device according to an embodiment of the present invention.

FIG. 7 is a schematic diagram of an air moving device according to an embodiment of the present invention.

FIG. 8 is a schematic diagram of an air moving device according to an embodiment of the present invention.

FIG. 9 is a schematic diagram of an air moving device according to an embodiment of the present invention.

FIG. 10 is a schematic diagram of an air moving device according to an embodiment of the present invention.

FIG. 11 is a schematic diagram of an air moving device according to an embodiment of the present invention.

FIG. 12 is a schematic diagram of an air moving device according to an embodiment of the present invention.

FIG. 13 is a schematic diagram of an air moving device according to an embodiment of the present invention.

FIG. 14 is a schematic diagram of an air moving device according to an embodiment of the present invention.

FIG. 15 is a schematic diagram of an air moving device according to an embodiment of the present invention.

FIG. 16 is a schematic diagram of an air moving device according to an embodiment of the present invention.

FIG. 17 is a schematic diagram of an air moving device according to an embodiment of the present invention.

FIG. 18 is a schematic diagram of an air moving device according to an embodiment of the present invention.

FIG. 19 is a schematic diagram of an air moving device according to an embodiment of the present invention.

FIG. 20 is a schematic diagram of a compound (multi-function) device according to an embodiment of the present invention.

FIG. 21 is a schematic diagram of a compound (multi-function) device according to an embodiment of the present invention.

FIG. 22 is a schematic diagram of air moving devices according to embodiments of the present invention.

FIG. 23 is a schematic diagram of an air moving device according to an embodiment of the present invention.

FIG. 24 is a schematic diagram of an air moving device according to an embodiment of the present invention.

FIG. 25 is a schematic diagram of an air moving device according to an embodiment of the present invention.

FIG. 26 is a schematic diagram of a mobile device according to an embodiment of the present invention.

FIG. 27 is a schematic diagram of an air moving device according to an embodiment of the present invention.

### DETAILED DESCRIPTION

The present invention addresses these challenges by providing a miniaturized, all-silicon cooling device. This device can function as a standalone chiplet or be integrated into advanced packaged System-in-Package (SiP) solutions. Fabricated using Micro-Electro-Mechanical Systems (MEMS) or standard semiconductor manufacturing processes, its core component is a piezoelectric-actuated film structure. This structure features a pair of opposing flaps that perform both common-mode and differential-mode movements simultaneously. The common-mode movement is driven by a modulation signal, while the differential-mode movement is driven by two demodulation signals. This combination of movements generates a constant, unidirectional airflow in the form of ultrasonic air pulses, which effectively dissipates heat.

Content of U.S. Pat. Nos. 11,943,585, 12,356,141, and application Ser. Nos. 19/007,580, 19/071,774 is incorporated herein by reference.

The technical features described in the embodiments of the present invention may be mixed or combined in various ways as long as there are no conflicts between them.

U.S. Pat. Nos. 11,943,585, 12,356,141, and application Ser. No. 19/007,580 disclose an air moving device or an air pulse generating device for air moving applications.

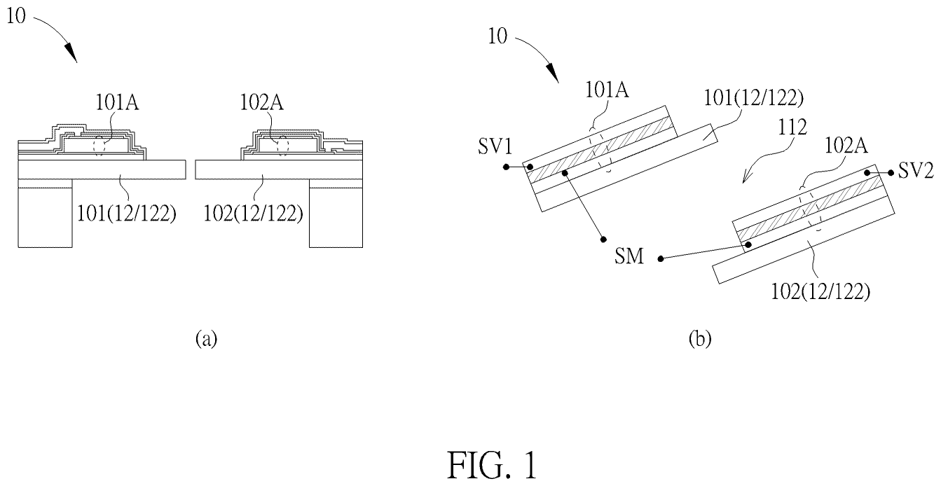

FIG. 1 is a schematic diagram of an air moving device 10 according to an embodiment of the present invention. The air moving device 10 is a semiconductor device which may be fabricated via MEMS (Micro Electro Mechanical Systems) or semiconductor fabrication/manufacturing process. The air moving device 10 comprises a film structure 12, which may be made of certain semiconductor/wafer material, e.g., silicon. On the film structure 12, actuator may be formed on the film structure 12.

The film structure 12 comprises a flap pair 122, where the flap pair 122 comprises a first flap 101 and a second flap 102 opposite to each other. The flaps 101 and 102 may be made of silicon. Actuators 101A and 102A may be formed on the flaps 101 and 102. The actuator 101A/102A comprises a piezoelectric layer comprising piezoelectric material (e.g., Lead Zirconate Titanate or PZT) sandwiched between a top electrode and a bottom electrode. The top electrode and the bottom electrode receive a demodulation signal SV and a modulation signal SM.

In an embodiment, the top electrode of the actuator 101A may receive a first demodulation signal SV1, the top electrode of the actuator 102A may receive a second demodulation signal SV2, and the bottom electrodes of the actuators 101A and 102A may receive the modulation signal SM. Hence, the flap pair 122 may perform a common-mode movement (because of the modulation signal SM) and a differential-mode movement (because of the demodulation signals SV1 and SV2), simultaneously. Due to the common-mode movement and the differential-mode movement, the air moving device 10 produces a plurality of air pulses at an ultrasonic pulse rate. During a specific time period (e.g., 0.1 seconds or more than 0.1 seconds), the air pulses are unipolar or produce one single direction. Hence, the air moving device 10 is able to produce an airflow constantly/consistently toward one direction over the specific time period. Nevertheless, a direction of the airflow produced by the air moving device 10 may be reversed. By properly adjusting parameter(s) of the demodulation signals SV1, SV2 and the modulation signal SM, the direction and the strength of the airflow produced by the air moving device 10 is adjustable.

The differential-mode movement of the flap pair 122 forms a virtual valve or an opening 112 at an opening rate corresponding to the ultrasonic pulse rate.

Wiring to the top and bottom electrode is not limited to specific scheme, and wiring schemes shown in FIG. 1 (specifically part (a) of FIG. 1) and following figures are just for illustrative purposes. In part (a) of FIG. 1, left side (flap 101) of part (a) of FIG. 1 illustrates a wiring scheme to top electrode, and right side (flap 102) of part (a) of FIG. 1 illustrates a wiring scheme to bottom electrode. Those skilled in the art shall be able to combine concept brought by left and right side of part (a) of FIG. 1 to obtain wiring scheme to both top and bottom electrodes.

Operation details of the air moving device 10 may be referred to U.S. Pat. Nos. 11,943,585, 12,356,141, and application Ser. No. 19/007,580, and manufacturing details of the air moving device 10 may be referred to application Ser. No. 19/071,774, which are not narrated herein for brevity.

Note that, (structure of) the air moving device 10 serves as a basic building block/unit of air moving device of the present invention and will appear repeatedly in the following embodiment.

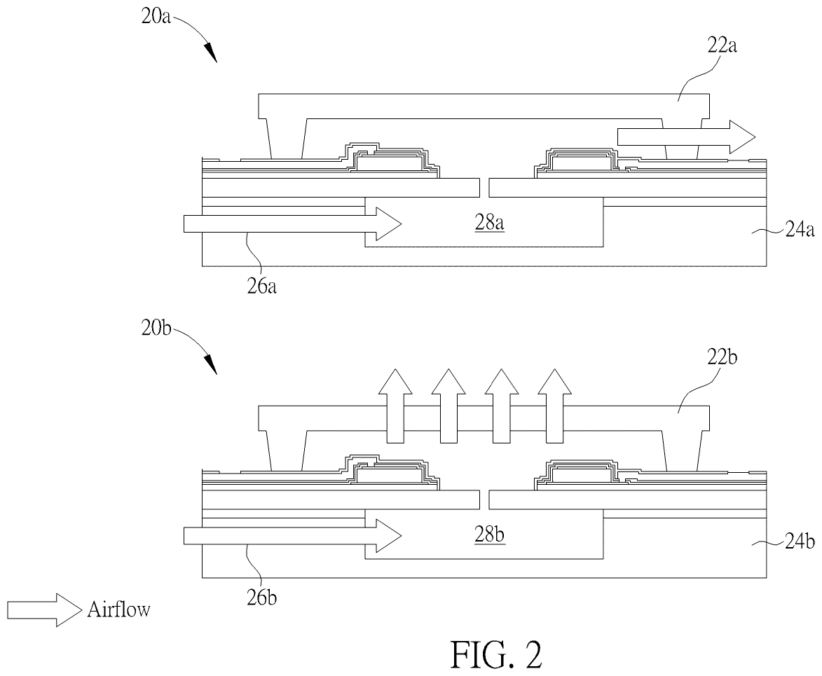

FIG. 2 illustrates a schematic diagram of an air moving device 20a and an air moving device 20b according to an embodiment of the present invention. The air moving device 20a/20b comprises the air moving device 10. In addition to the air moving device 10, the air moving device 20a/20b comprises a covering structure 22a/22b. The covering structure 22a/22b may be made of wafer/semiconductor material, e.g., silicon. In an embodiment, the film structure and the covering structure may be both made of the same wafer/semiconductor material (e.g., silicon), which may simplify the manufacturing complexity.

The covering structure 22a may be a side-firing lid, allowing airflow flowing (outward/inward) via a side of the covering structure 22a. The covering structure 22b may be a top-firing lid, allowing airflow flowing (outward/inward) via a top of the covering structure 22b.

Moreover, the air moving device 20a/20b may be formed on a base 24a/24b, where the base 24a/24b may be also made of the wafer/semiconductor material, e.g., silicon. In an embodiment, the base, the film structure and the covering structure (of the air moving device) may be both made of the same wafer/semiconductor material (e.g., silicon), which may simplify the manufacturing complexity.

In an embodiment, an air pathway 26a/26b and a back cavity 28a/28b may be formed within the base 24a/24b, allowing an airflow flowing from an ambience, through the air pathway 26a/26b and to the back cavity 28a/28b.

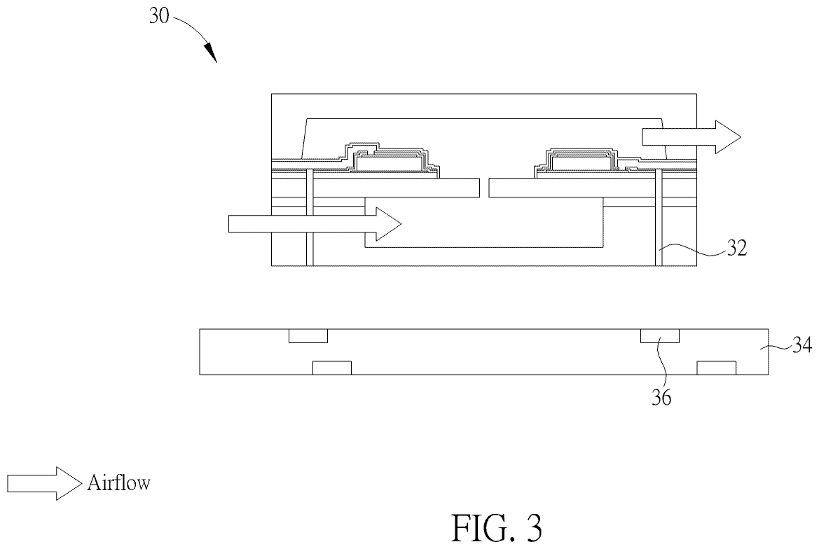

FIG. 3 is a schematic diagram of an air moving device 30 according to an embodiment of the present invention. The air moving device 30 is similar to the air moving device 20a. Different from 20a, through silicon via (TSV) 32 is formed within the air moving device 30. The TSV 32 may be configured to provide electrical connection to pad 36 formed on printed circuit board (PCB) 34.

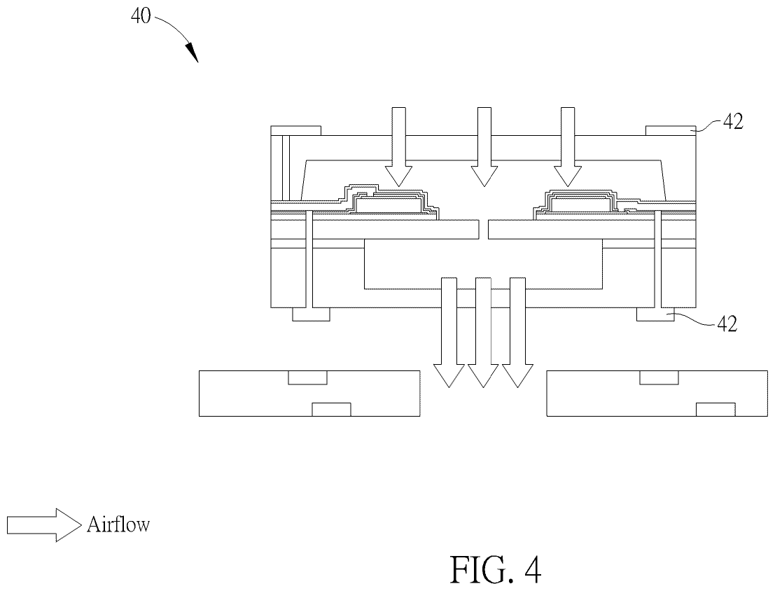

FIG. 4 is a schematic diagram of an air moving device 40 according to an embodiment of the present invention. The air moving device 40 is similar to the air moving device 30. The airflow produced by the air moving device 30 is lateral, and the airflow produced by the air moving device 40 is vertical. In addition, the air moving device 40 comprises pad(s) 42, disposed on a top of covering structure or underneath a bottom of base, to interface with other chips in chip stack.

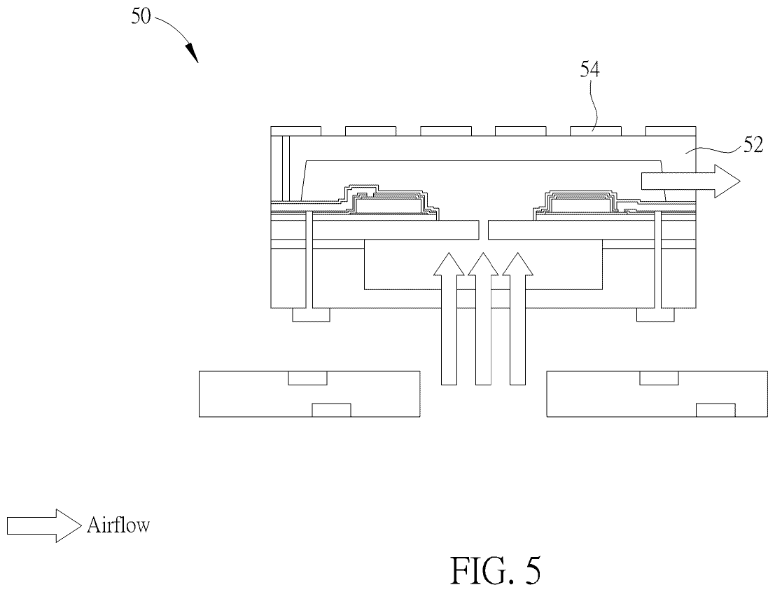

FIG. 5 is a schematic diagram of an air moving device 50 according to an embodiment of the present invention. The air moving device 50 is similar to the air moving devices 30 and 40. The air moving device 50 comprises side-firing covering structure 52 and pads 54 disposed on the covering structure 52.

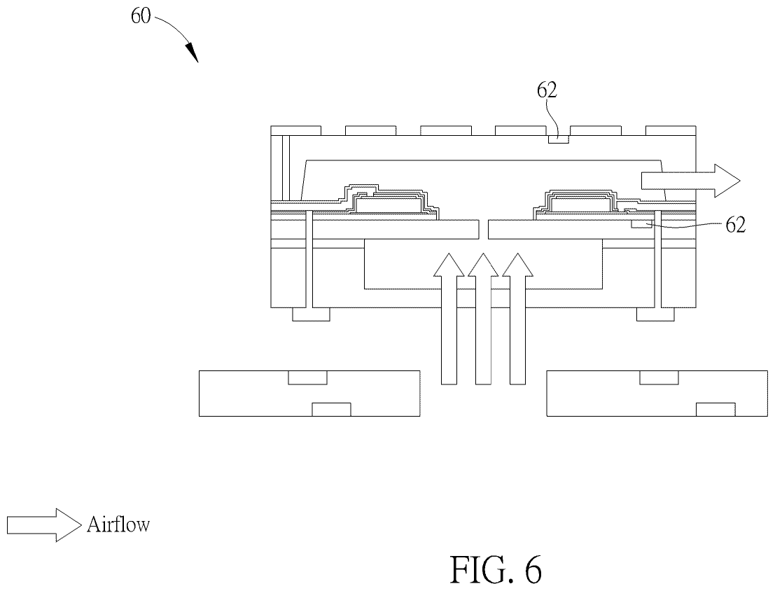

FIG. 6 is a schematic diagram of an air moving device 60 according to an embodiment of the present invention. The air moving device 60 is similar to the air moving device 50. Different from 50, the air moving device 60 further comprises temperature sensor(s) (e.g., thermistors) 62. The temperature sensor(s) 62 may be disposed in suitable place within base or film/covering structure within the air moving device 60. The temperature sensor(s) 62 may be coupled to a controller (not shown), where the controller may adjust a strength of the airflow according to a temperature result sensed by the temperature sensor(s) 62.

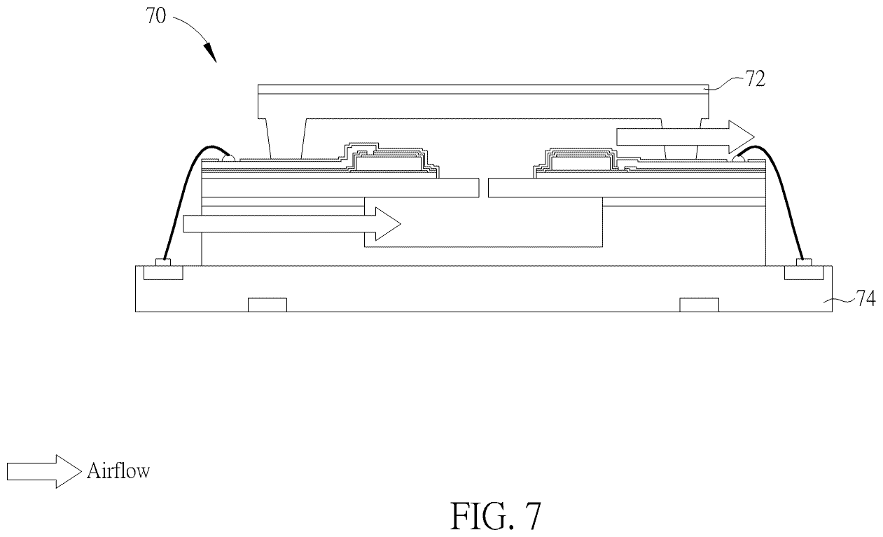

FIG. 7 is a schematic diagram of an air moving device 70 according to an embodiment of the present invention. The air moving device 70 is similar to the air moving device 20a. Different from 20a, the air moving device 70 comprises a thermal interface material (TIM) 72 on the covering structure. The air moving device 70 may have contact with another hot chip (heat generating device) via the TIM 72 to dissipate heat from the hot chip (heat generating device). Also, as shown in FIG. 7, the air moving device 70 is wire bonding to a PCB 74.

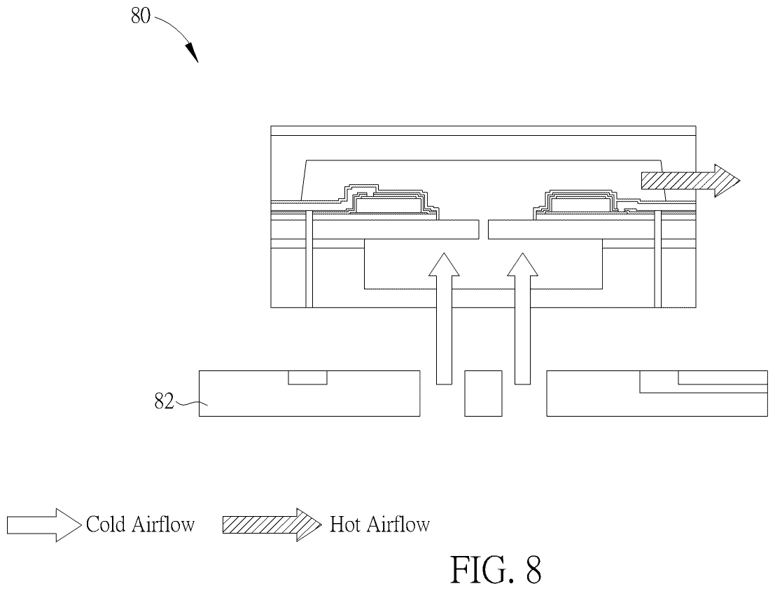

FIG. 8 is a schematic diagram of an air moving device 80 according to an embodiment of the present invention. The air moving device 80 is similar to the air moving device 70. Different from 70, the air moving device 80 may be disposed on a flexible PCB (FPCB) 82, providing assembly flexibility of the air moving device.

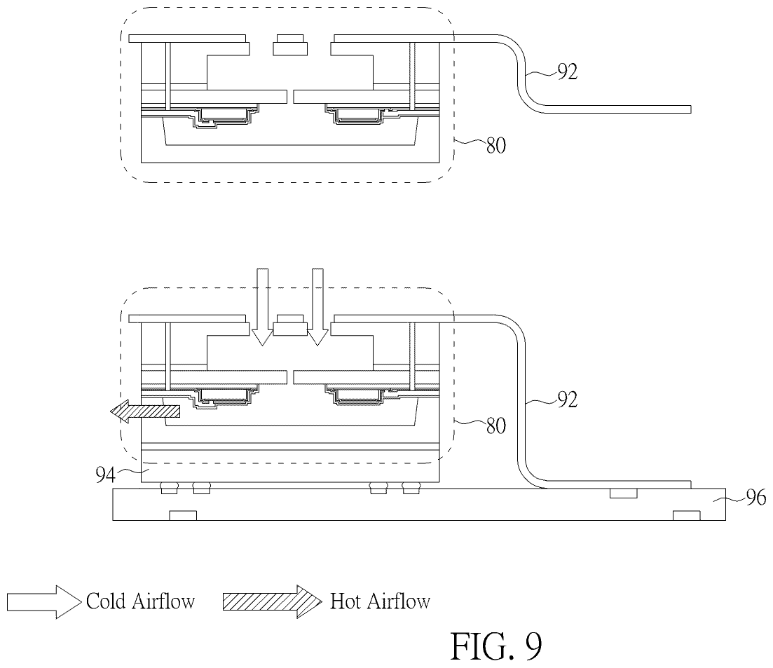

For example, FIG. 9 illustrates an application of the air moving device 80 according to an embodiment of the present invention. The air moving device 80 is flipped and disposed on a hot chip (heat generating device) 94. The hot chip (heat generating device) 94 may be a processor such as CPU (central processing unit) or GPU (graphic processing unit). Heat generated by the heat generating device 94 may be dissipated by the airflow produced by the air moving device 80. Through FPCB 92, electrical signal(s) from PCB 96 may be delivered to the air moving device 80.

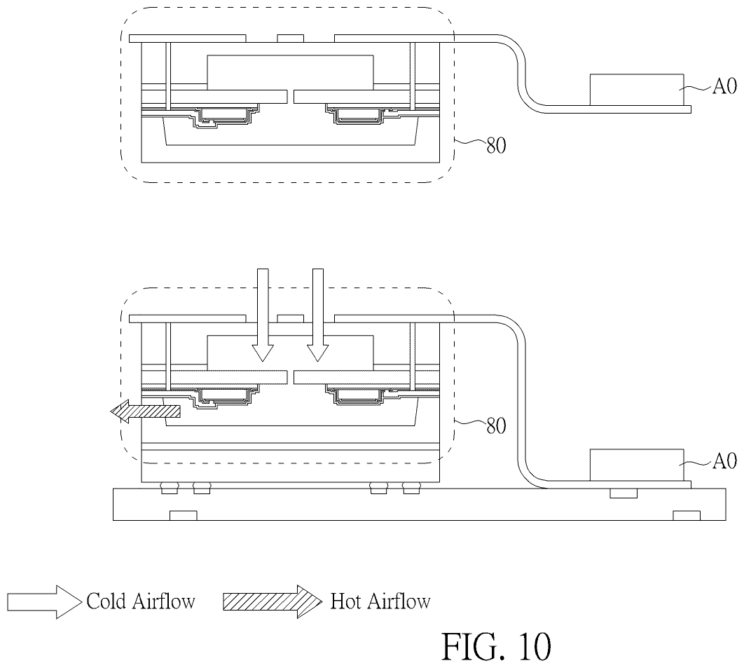

FIG. 10 illustrates another application of the air moving device 80 according to an embodiment of the present invention. Different from FIG. 9, in FIG. 10 a driving circuit A0 is connected to FPCB to provide electrical signal(s) to the air moving device 80.

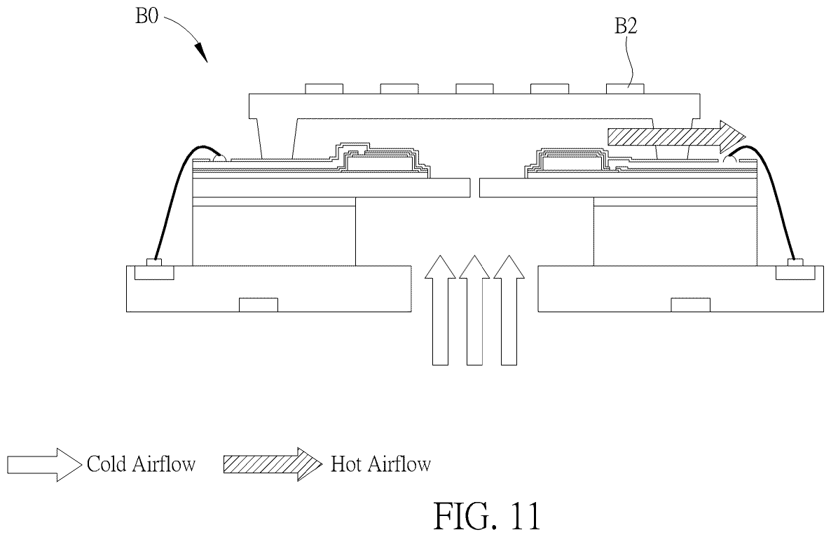

FIG. 11 is a schematic diagram of an air moving device B0 according to an embodiment of the present invention. The air moving device B0 comprise pads B2 to provide thermal and/or electrical contact to another chip (not shown).

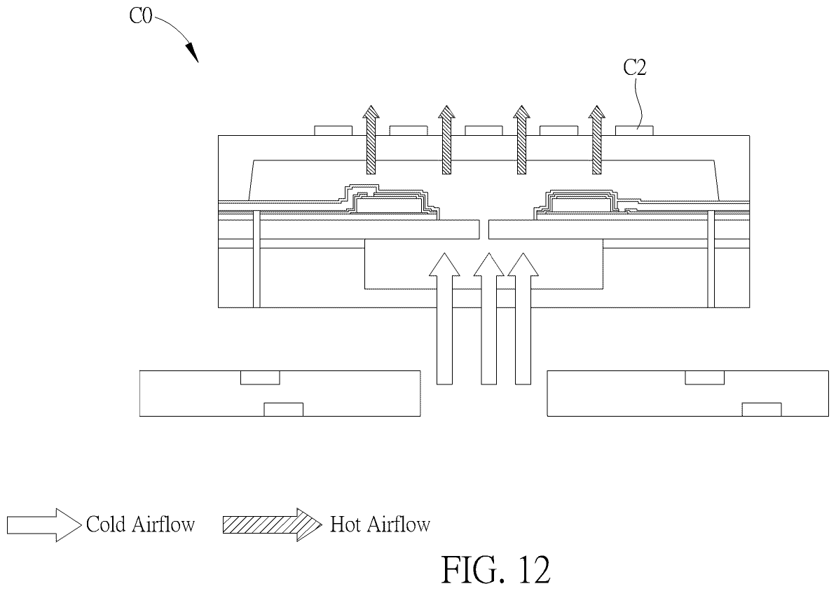

FIG. 12 is a schematic diagram of an air moving device C0 according to an embodiment of the present invention. The air moving device C0 is similar to the air moving device B0. The air moving device C0 provides top-firing while the air moving device B0 provides side-firing.

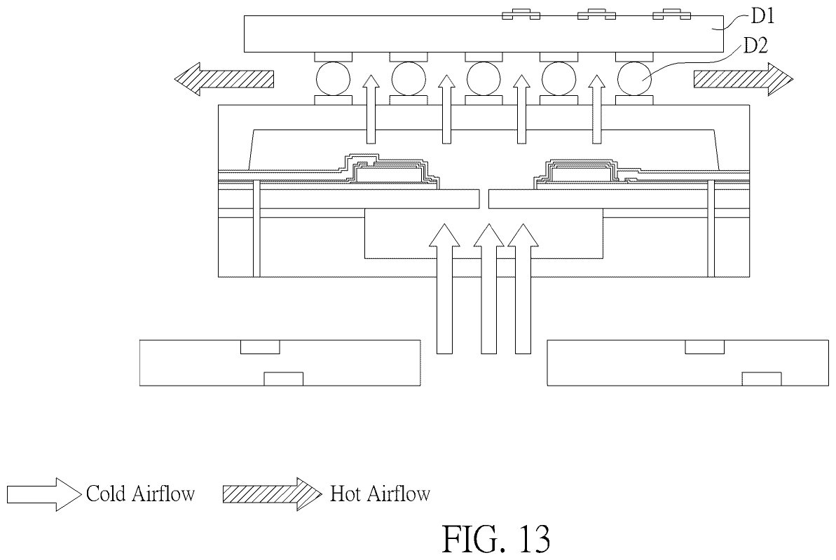

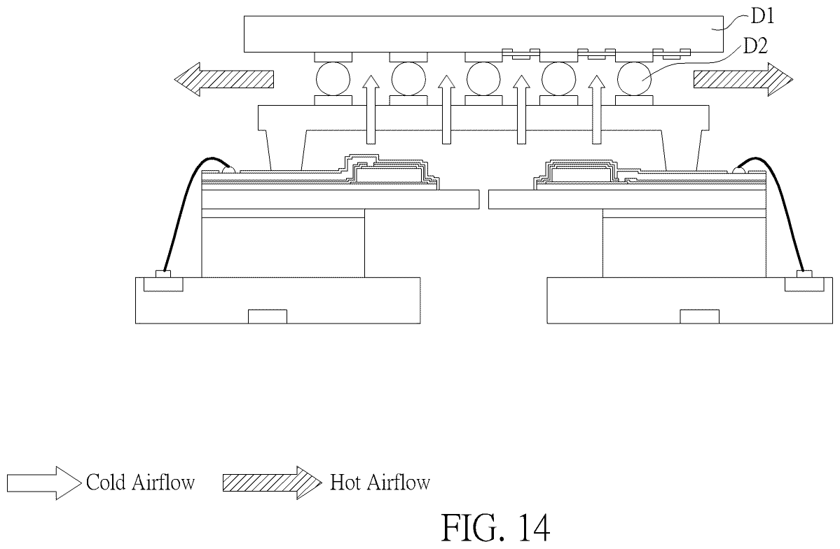

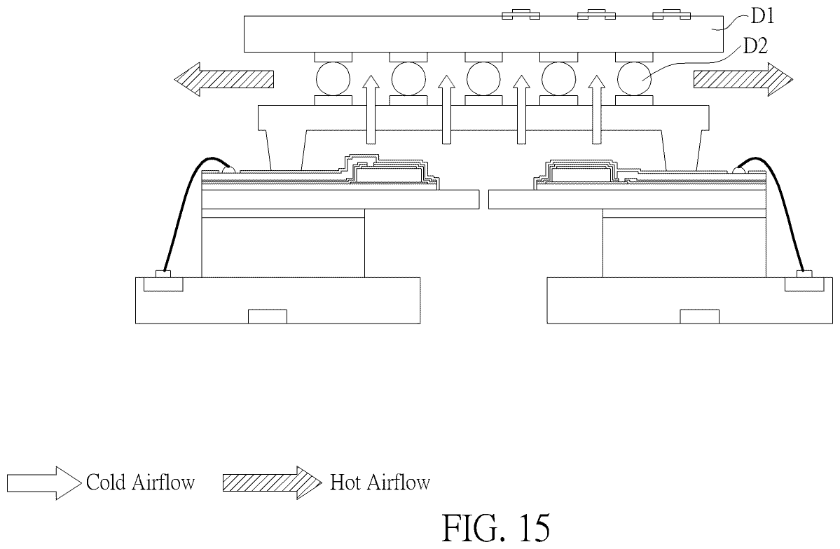

FIGS. 13-15 illustrate applications of the air moving devices of the present invention. In FIGS. 13-15, the air moving devices of the present invention may be connected to an integrated circuit (IC) chip D1 via connectors D2. The connectors D2 may be (thermal and/or electrical) conductive balls, e.g., solder balls. In FIGS. 13 and 15 the air moving devices face a backside of the IC chip D1, while in FIG. 14 the air moving devices face a front side of the IC chip D1.

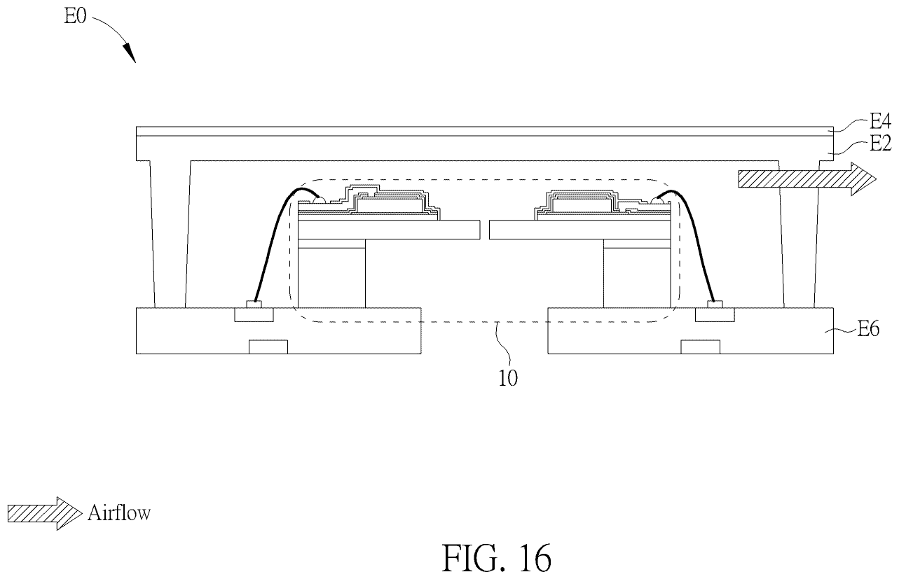

FIG. 16 is a schematic diagram of an air moving device E0 according to an embodiment of the present invention. The air moving device E0 comprises a side-firing covering structure E2 and TIM E4 disposed on the covering structure E2. Under the covering structure E2, the air moving device 10 is wire bonding to a PCB E6.

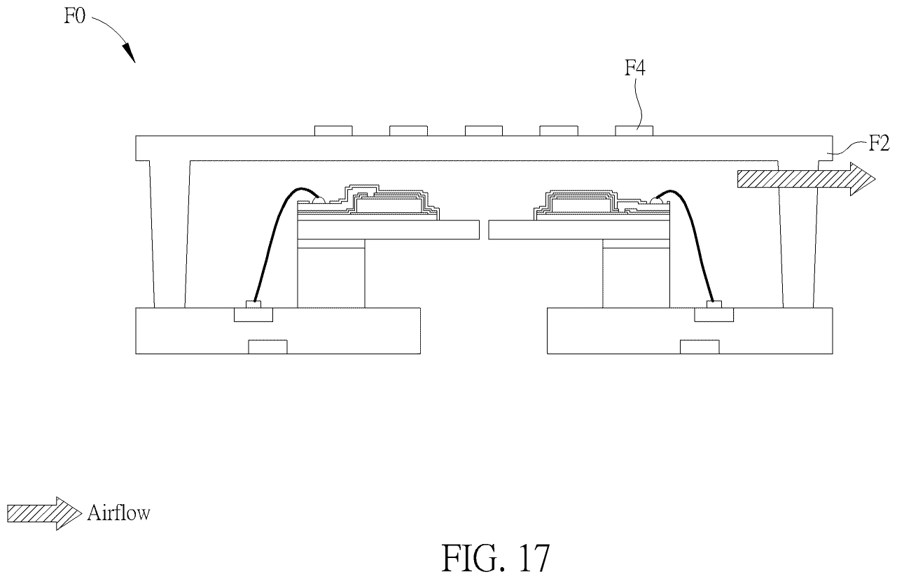

FIG. 17 is a schematic diagram of an air moving device F0 according to an embodiment of the present invention. The air moving device F0 is similar to the air moving device E0. Different from E0, the air moving device F0 comprises pads F4 disposed on a top of the covering structure F2, instead of TIM.

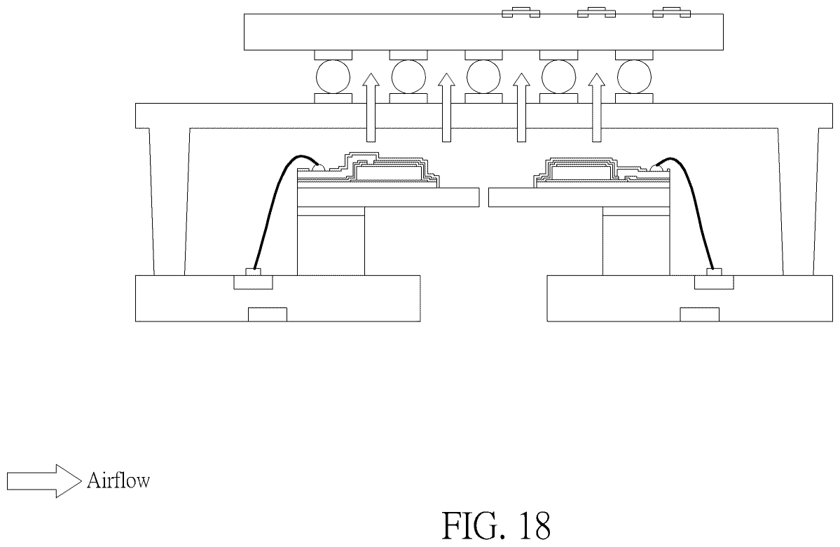

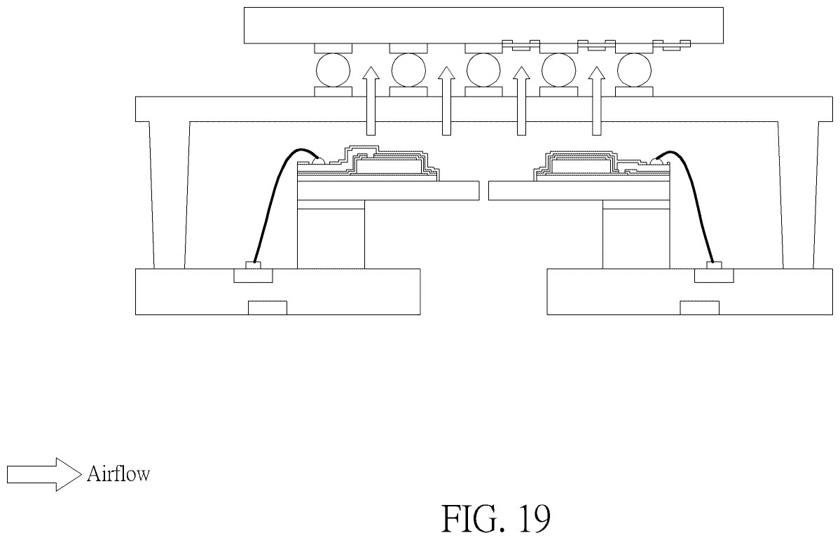

FIGS. 18-19 are similar to FIGS. 14-15, except different shape/type of covering structure is employed in FIGS. 18-19.

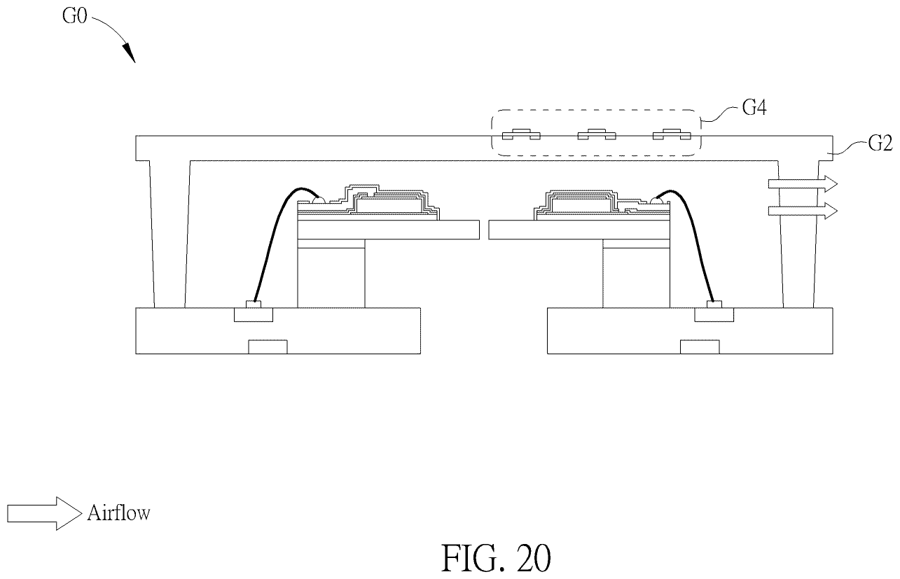

FIG. 20 is a schematic diagram of a compound (multi-function) device G0 according to an embodiment of the present invention. The compound (multi-function) device G0 comprises a covering structure G2 made of wafer/semiconductor material, e.g., silicon. Since the covering structure G2 is made of wafer/semiconductor material, an IC chip G4 is formed on the covering structure G2, providing multiple functionalities of chiplet/tile associated with the compound (multi-function) device G0. For example, airflow may be produced to dissipate heat generated by the IC chip G4 formed on the covering structure G2. Note that, the compound (multi-function) device G0 may also be regarded as an air moving device.

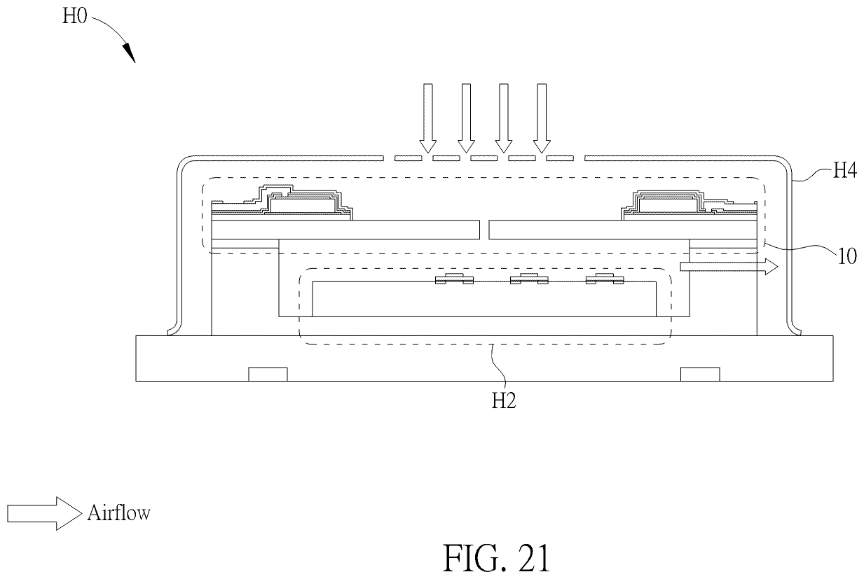

FIG. 21 is a schematic diagram of a compound (multi-function) device H0 according to an embodiment of the present invention. The compound (multi-function) device H0 comprises the air moving device 10, an IC chip H2 and a metal lid H4. The air moving device 10 may cover the IC chip H2 (the IC chip H2 can be viewed as being disposed within the back cavity of the air moving device 10 or within the cavity formed within the base of the air moving device 10) and produce an airflow to dissipate heat generated by the IC chip H2. Note that, the compound (multi-function) device H0 may also be regarded as an air moving device.

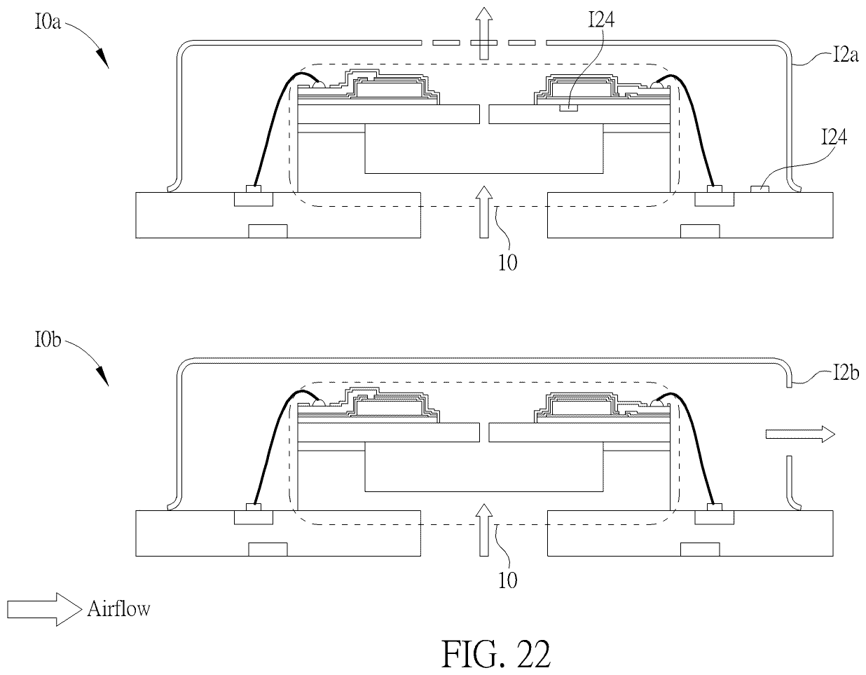

FIG. 22 illustrates a schematic diagram of an air moving device I0a and an air moving device I0b according to an embodiment of the present invention. The air moving device I0a/I0b comprises the air moving device 10 wire bonding to PCB. The air moving device I0a/I0b comprises a covering structure (e.g., (metal) lid) I2a/I2b which may be top/side-firing.

In addition, in the embodiment shown in FIG. 22, the air moving device I0a may comprise temperature sensor(s) I24 disposed in suitable place within the air moving device. A controller may be connected to the temperature sensor(s) I24 to control a strength of airflow produced by the air moving device.

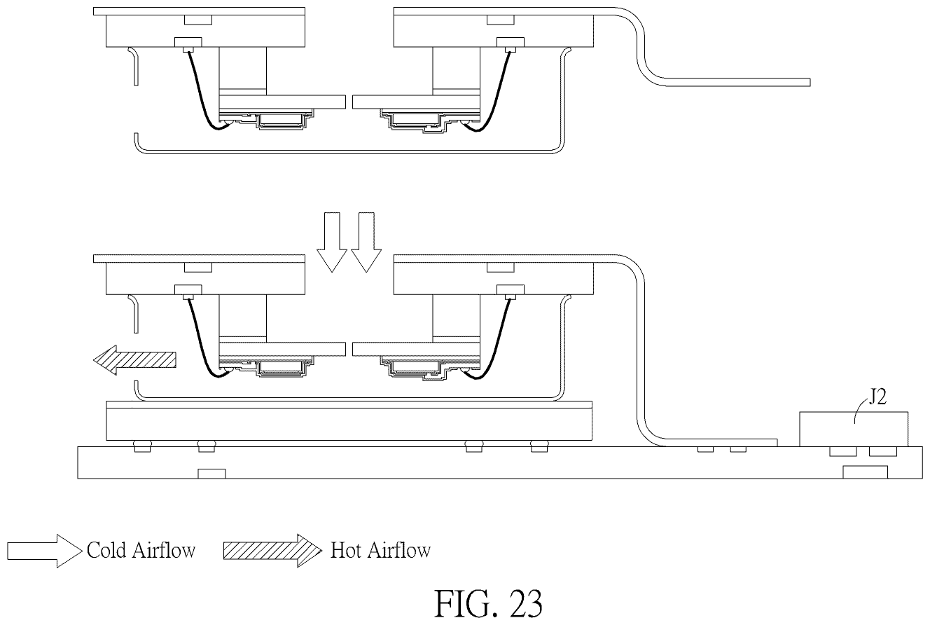

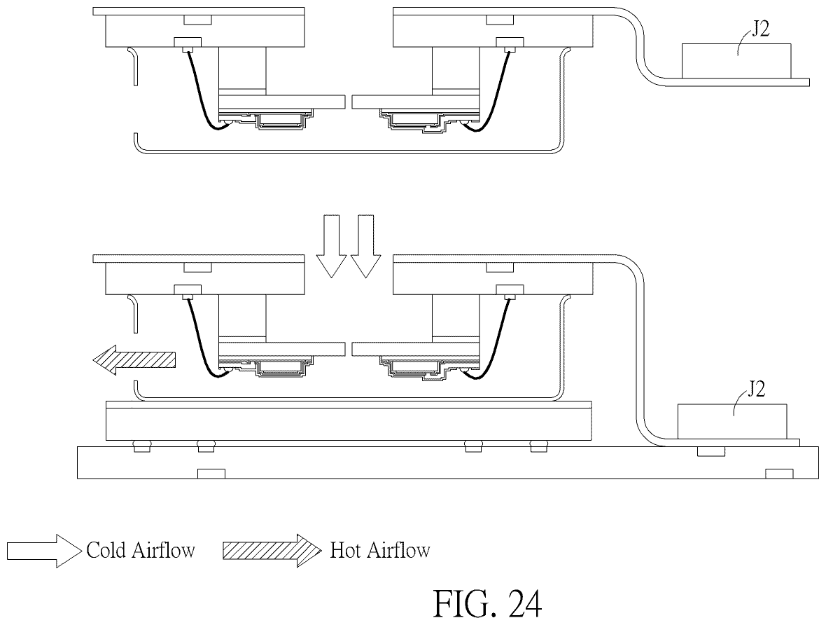

FIGS. 23-24 illustrates applications of the air moving device I0b similar to FIGS. 9-10.

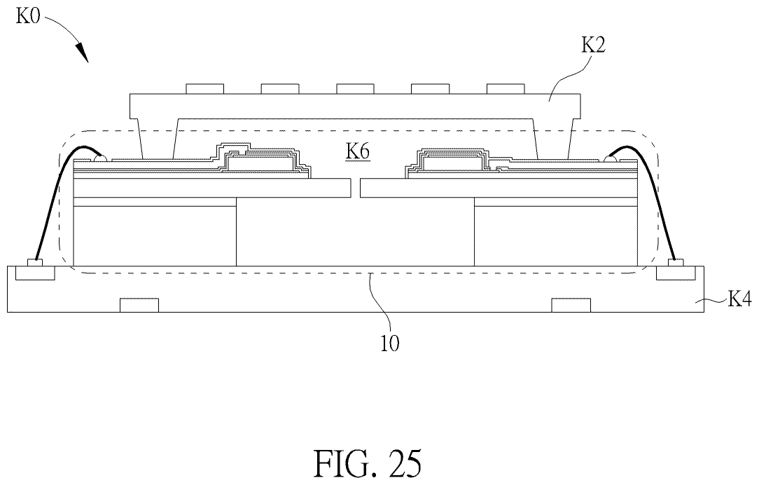

FIG. 25 is a schematic diagram of an air moving device K0 according to an embodiment of the present invention. The air moving device K0 comprises the air moving device 10 and the covering structure K2. The air moving device 10 is attached to a PCB K4. The covering structure K2 may be made of wafer/semiconductor material. The covering structure K2 may be a sawed/diced wafer. Furthermore, the covering structure K2 may be a sawed/diced wafer with back trench. The back trench of the covering structure K2 and space above the film structure of the air moving device 10 would form a front chamber K6 (between the film structure and the covering structure) of the air moving device K0. Upon the wafer (covering structure) K2, an IC chip or pad(s) may be formed thereon.

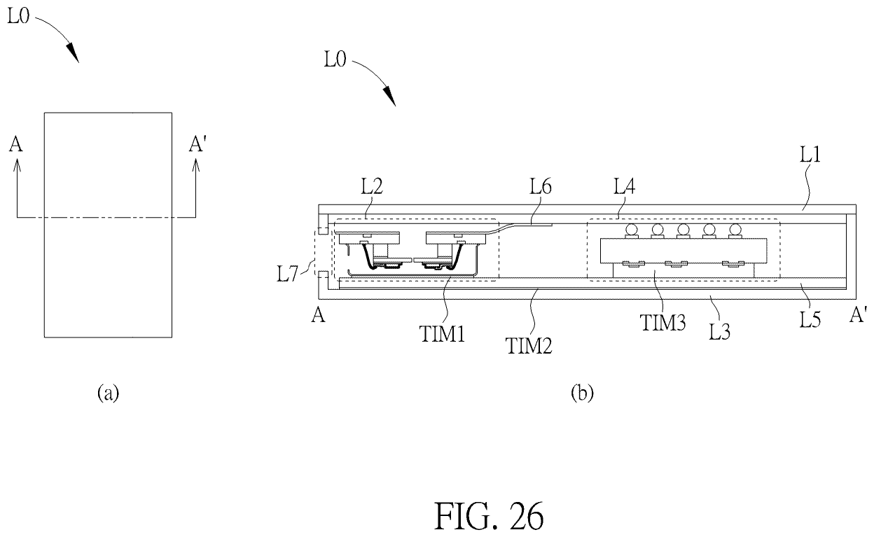

FIG. 26 illustrates a mobile device L0 according to an embodiment of the present invention. Part (a) of FIG. 26 illustrates a top view of the mobile device L0 and part (b) of FIG. 26 illustrates a cross sectional view of the mobile device L0 along an A-A′ line. The mobile device L0 may be a mobile electronic device such as a mobile phone or a mobile tablet computer. The mobile device L0 comprises a hot chip L4, which may be a heat generating device such as a processor. To prevent the hot chip (processor) L4 from throttling, heat generated by/from the hot chip (processor) L4 needs to be dissipated as efficiently as possible. In order to dissipate heat generated by/from the hot chip (processor) L4, a heat spreader (e.g., a vapor chamber) L5 is included in the mobile device L0, to spread the heat over the heat spreader L5.

Furthermore, the mobile device L0 may comprises a side-firing air moving device L2 to produce airflow to dissipate heat carried on the heat spreader L5. In an embodiment, the air moving device L2 may be disposed by an edge of the heat spreader L5 or the mobile device L0. The airflow may be produced toward a port L7 formed within a housing L3 on the edge of the mobile device L0. A glass L1 may be included to protect screen of the mobile device L0.

In the embodiment shown in FIG. 26, the air moving device L2 may be similar to the air moving device I0b (shown in FIG. 22) and attached on an FPCB L6, which is not limited thereto.

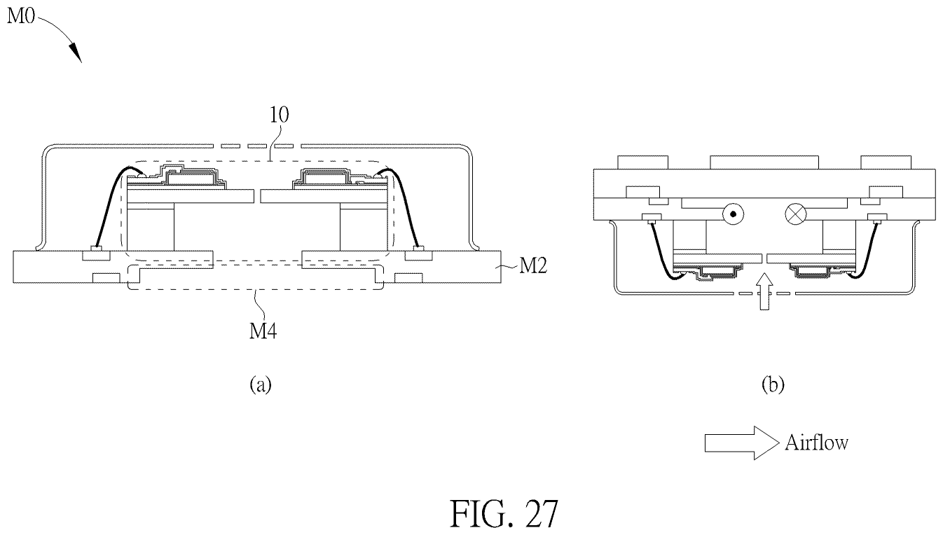

FIG. 27 is a schematic diagram of an air moving device M0 according to an embodiment of the present invention. The air moving device M0 comprises the air moving device 10 disposed on a base or substrate (e.g., PCB) M2, where the base/substrate M2 is channeled. It means that a channel M4 is formed within the base/substrate M2, allowing an airflow flowing therethrough. When the air moving device M0 is assembled or integrated (as part (b) of FIG. 27 shows). The airflow may flow in or out with respect to the figure. Note that, in part (b) of FIG. 27 the airflow is top-intake (which means the air moving device M0 comprises a top-intake covering structure), which is not limited thereto. The airflow may be also side-intake (which means the air moving device may comprise a side-intake covering structure), which is also within the scope of the present invention.

A key advantage of this all-silicon design is its high integrability and flexibility. The entire device (including the base, actuator, and lid) can be made from the same semiconductor material, such as silicon, which simplifies the manufacturing process. The device can be configured for either side-firing or top-firing airflow and can be integrated with temperature sensors for precise thermal control. It can be directly attached to a Printed Circuit Board (PCB) or Flexible Printed Circuit Board (FPCB) and can even be stacked with other chips using Through-Silicon Vias (TSVs) or conductive pads. These features make it an ideal solution for addressing the critical thermal challenges in advanced packaging technologies.

The presented all-silicon cooling device offers a subtle yet significant advancement in thermal management. By fabricating the entire device from silicon, this technology seamlessly integrates with modern semiconductor manufacturing processes, making it well-suited for advanced packaging and chiplet designs. The use of a channeled PCB to facilitate airflow presents a novel approach to overcome space constraints, ensuring efficient heat dissipation in compact assemblies where traditional airflow is compromised. This invention stands poised to be a critical component for enabling reliable operation in the next generation of high-performance electronic devices.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An air moving device, comprising:
a film structure comprising a flap pair, wherein the flap pair comprises a first flap and a second flap opposite to each other;
a first actuator disposed on the first flap and a second actuator disposed on the second flap;
wherein the first actuator comprises a first electrode and a second electrode, and the second actuator comprises a third electrode and a fourth electrode;
wherein the first electrode receives a first demodulation signal and the third electrode receives a second demodulation signal, such that the flap pair performs a differential-mode movement;
wherein the second electrode and the fourth electrode receive a modulation signal, such that the flap pair performs a common-mode movement.

2. The air moving device of claim 1,
wherein the air moving device produces a plurality of air pulses at an ultrasonic pulse rate.

3. The air moving device of claim 2,
wherein the differential-mode movement of the flap pair forms a virtual valve or an opening at an opening rate corresponding to the ultrasonic pulse rate.

4. The air moving device of claim 2,
wherein during a time period, the plurality of air pulses are unipolar.

5. The air moving device of claim 1, comprising:
a covering structure;
wherein a front chamber is formed between the film structure and a covering structure.

6. The air moving device of claim 5,
wherein the covering structure is made of a wafer material or made of silicon.

7. The air moving device of claim 5,
wherein the film structure and the covering structure are made of the same material.

8. The air moving device of claim 5,
wherein an integrated circuit chip is formed on the covering structure.

9. The air moving device of claim 5,
wherein the air moving device is connected to an integrated circuit chip via connectors or conductive balls.

10. The air moving device of claim 9,
wherein the connectors or conductive balls are disposed between the covering structure and the integrated circuit chip.

11. The air moving device of claim 5,
wherein the air moving device comprises pads disposed on a top of the covering structure.

12. The air moving device of claim 5,
wherein the air moving device comprises a thermal interface material disposed on a top of the covering structure.

13. The air moving device of claim 1, comprising:
a top-firing covering structure.

14. The air moving device of claim 1, comprising:
a side-firing covering structure.

15. The air moving device of claim 1,
wherein the air moving device is disposed on a flexible printed circuit board.

16. The air moving device of claim 15,
wherein a driving circuit is connected to the flexible printed circuit board to provide an electrical signal to the air moving device.

17. The air moving device of claim 1,
wherein a through silicon via is formed within the air moving device.

18. The air moving device of claim 1,
wherein the air moving device is disposed within a mobile device;
wherein the air moving device is attached to a heat spreader disposed within the mobile device.

19. The air moving device of claim 1,
wherein the air moving device is formed on a base;
wherein a back cavity is formed within the base;
wherein an airflow flows between an ambience and the back cavity.

20. The air moving device of claim 1,
wherein the air moving device is wire bonding to a printed circuit board.

21. The air moving device of claim 1,
wherein an integrated circuit chip is disposed within a back cavity of the air moving device.

22. The air moving device of claim 1, comprising:
a temperature sensor.

23. The air moving device of claim 22,
wherein a controller is connected to the temperature sensor to control a strength of an airflow produced by the air moving device.

24. The air moving device of claim 1,
wherein the air moving device is disposed on a base or a substrate;
wherein a channel is formed within the base or the substrate.

25. The air moving device of claim 24,
wherein an airflow produced by the air moving device flows through the channel.

26. The air moving device of claim 1,
a top-intake covering structure or a side-intake covering structure.
